(19) United States
(12) Patent Application Publication
(10) Pub. No.: US 2025/0174518 A1
(43) Pub. Date: May 29, 2025

(54) THERMAL ISOLATION FOR HARDWARE COMPONENT PACKAGE

(71) Applicant: Microsoft Technology Licensing, LLC, Redmond, WA (US)

(72) Inventors: Rui JIN, Mountain View, CA (US); Minseok OH, Santa Clara, CA (US); Frank C HOLLOWAY, Loveland, CO (US); Mohan Arvind KIRLOSKAR, Lakeway, TX (US)

(73) Assignee: Microsoft Technology Licensing, LLC, Redmond, WA (US)

(21) Appl. No.: 18/521,523

(22) Filed: Nov. 28, 2023

(51) Int. Cl. H01L 23/38; H01L 27/146; H10N 19/00

(52) U.S. Cl. CPC H01L 23/38; H10F 39/804; H10N 19/00; H01L 2224/48091; H01L 2224/48225; H01L 2224/48235

(57) ABSTRACT

A hardware component package includes a temperature-sensitive hardware component having a first surface and a second surface opposite from the first surface. A substrate is coupled with the temperature-sensitive hardware component via a wire bond connected to the first surface of the temperature-sensitive hardware component. A package enclosure is coupled with the second surface of the temperature-sensitive hardware component. The package enclosure includes a central portion and a lateral portion formed from separate pieces of material and separated by a thermal isolation layer. A thermoelectric cooler (TEC) is disposed between the second surface of the temperature-sensitive hardware component and the package enclosure, such that at least some heat generated by the temperature-sensitive hardware component is dissipated to the package enclosure via the TEC.

### BACKGROUND

Hardware devices, such as image sensors, are widely used in various applications ranging from consumer electronics to industrial and scientific instrumentation. During operation, these devices generate significant amounts of heat due to electrical power consumption and the concentration of electronic activity in a small area. Excessive heat accumulation can adversely affect the performance, accuracy, and longevity of the hardware, leading to issues such as increased noise, reduced sensitivity, thermal drift, and in extreme cases, physical damage to the device components.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

A hardware component package includes a temperature-sensitive hardware component having a first surface and a second surface opposite from the first surface. A substrate is coupled with the temperature-sensitive hardware component via a wire bond connected to the first surface of the temperature-sensitive hardware component. A package enclosure is coupled with the second surface of the temperature-sensitive hardware component. The package enclosure includes a central portion and a lateral portion formed from separate pieces of material and separated by a thermal isolation layer. A thermoelectric cooler (TEC) is disposed between the second surface of the temperature-sensitive hardware component and the package enclosure, such that at least some heat generated by the temperature-sensitive hardware component is dissipated to the package enclosure via the TEC.

### BRIEF DESCRIPTION OF THE DRAWINGS

FIG. 1 schematically depicts an example electronic device including a hardware component package communicatively coupled with a logic controller.

FIG. 2 schematically depicts a sectional view of aspects of an example hardware component package.

FIG. 3 schematically depicts a sectional view of aspects of another example hardware component package.

FIG. 4 schematically depicts a sectional view of aspects of another example hardware component package.

FIG. 5 schematically depicts a sectional view of aspects of another example hardware component package.

FIG. 6 schematically depicts a sectional view of aspects of another example hardware component package.

FIG. 7 schematically depicts a sectional view of aspects of an example image sensor.

### DETAILED DESCRIPTION

In the operation of electronic devices, various components including processors, memory chips, power supplies, and other circuitry inherently generate heat as a byproduct of their normal function. This heat, if not properly managed, can propagate through the device via conduction, convection, and/or radiation, adversely affecting adjacent components. Particularly vulnerable to such thermal propagation are temperature-sensitive components such as image sensors.

Conduction refers to the process by which heat is directly transmitted through a substance when there is a difference of temperature between adjoining regions. In the context of electronic devices, conduction can occur through the solid materials that make up the substrates (e.g., printed circuit boards (PCBs)), integrated circuits, and other intra-device connective structures of the electronic device. Heat from a high-power component can be conducted through these materials to a temperature-sensitive component, such as an image sensor, thereby elevating its temperature.

Additionally, or alternatively, convection—the transfer of heat by the physical movement of a fluid such as air or a cooling liquid—can exacerbate this problem. In electronic devices, the heat generated by components can cause localized warming of the air within the device casing. This warm air can circulate within the device, further distributing the heat. If this convective flow of air passes over or near a temperature-sensitive component, it can transfer additional heat to the component, thereby increasing its temperature.

Additionally, or alternatively, temperature-sensitive components within a device housing can be heated by other heat-generating components through radiation when the latter emit electromagnetic radiation, particularly in the infrared spectrum, as a result of their elevated temperatures. This emitted radiation propagates through the housing and is absorbed by the temperature-sensitive components, increasing their thermal energy. The absorbed radiation is then converted into heat, leading to a temperature rise in these components.

This thermal propagation presents a significant challenge in the cooling of temperature-sensitive components. As heat diffuses from other components in the device, such heat may increase the temperature of the temperature-sensitive component, increasing the thermal load applied to the device's cooling system (e.g., heat sink, fan, liquid cooling solution). The additional thermal load can strain the cooling system, requiring more robust or complex cooling solutions. This problem is compounded in high-density electronic configurations where space constraints limit the size and effectiveness of cooling systems, and in portable or battery-powered devices where power efficiency is a premium concern.

Accordingly, the present disclosure is directed to systems and techniques that may be used to isolate temperature-sensitive components such as image sensors from the conductive, convective, and/or radiative heat transfer effects caused by neighboring electronic components within a device. In some examples, this beneficially reduces the thermal load on a cooling system used to cool the temperature-sensitive components, thereby reducing the overall demand on the cooling system and enhancing the device's performance and longevity. In some examples, this can be used to reduce the size of the cooling system, which may enable a reduction in device size. Additionally, or alternatively, the techniques described herein can beneficially reduce device power consumption by reducing the amount of power consumed by a cooling system while maintaining the temperature-sensitive component at an acceptable operating temperature.

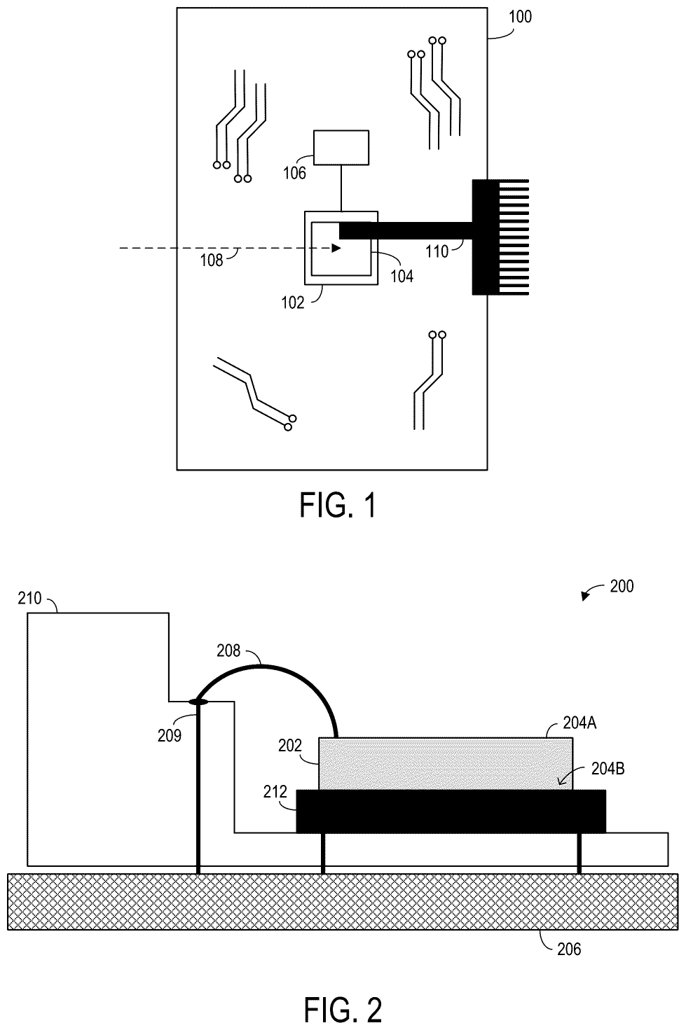

FIG. 1 schematically represents aspects of an example electronic device 100. Electronic device 100 includes a hardware component package 102, used to encapsulate a temperature-sensitive component 104. The present disclosure primarily focuses on scenarios where the temperature-sensitive component takes the form of an image sensor. However, it will be understood that this is only one non-limiting example. In general, a wide variety of different types of computer hardware may be sensitive to temperature changes, and therefore may benefit from use of the package-level and or die-level thermal isolation techniques described herein.

In the context of an image sensor, a hardware component package may be described as a comprehensive assembly that encapsulates the image sensor chip and provides mechanical support, electrical connections, and environmental protection to facilitate its functionality and reliability within an electronic device. For instance, as will be described in more detail below, an image sensor package may include a sensor die, a substrate, one or more wire bonds connecting the sensor die to traces on the substrate, a package enclosure, and/or other suitable components. It will be understood that similar and/or alternative components may be used in cases where the temperature-sensitive hardware component is not an image sensor, but rather is some other type of temperature-sensitive component.

As shown in FIG. 1, electronic device 100 additionally includes a logic controller 106 communicatively coupled with the temperature-sensitive hardware component 104. For instance, logic controller 106 may be implemented as a processor, application-specific integrated circuit, and/or other suitable computer logic component. In the example of FIG. 1, the temperature-sensitive hardware component is an image sensor that receives light 108 and translates the light into electrical signals that are propagated to logic controller 106. Data generated by the image sensor and processed by the logic controller may be used to output image data. For instance, electronic device 100 may take the form of a camera that uses an image sensor and logic controller together to capture and output images of a surrounding environment.

During operation of the electronic device, various components of the device may generate heat as they consume electrical power, including temperature-sensitive component 104 and logic controller 106. For instance, image sensors consume electrical power to activate the sensor's pixels, read out the data, and perform internal processing. The electrical current flowing through the sensor generates heat due to resistance. Furthermore, each pixel in an image sensor converts light into an electrical charge. This process, and the subsequent readout of the charge (translating it into a digital value), generates a small amount of heat. When multiplied by the large number of pixels on a sensor (as in high-resolution cameras), this can lead to significant heat buildup, especially during prolonged use or when operating at high frame rates.

As discussed above, the performance of an image sensor (and/or other types of temperature-sensitive hardware components) can be negatively affected by increasing temperature. As examples, when the temperature of an image sensor increases, the image sensor may exhibit any or all of the following types of performance degradation: an increase in digital noise due to increased thermal agitation of electrons, leading to grainier images with less clarity; a reduction in the dynamic range of the image sensor; a reduction in color accuracy of the image sensor caused by a change in the response of the sensor's color filters; an increase in dark current, potentially resulting in increased background noise in captured images; and/or reduced lifetime and reliability due to increased wear-and-tear on the image sensor's physical components. As such, devices may include some type of cooling system for cooling the image sensor, or other type of temperature-sensitive component, for dissipating heat produced by the component during operation and managing the component's temperature.

To this end, electronic device 100 includes a simplified representation of a cooling system 110, taking the form of a heat sink that is thermally coupled with hardware component package 102. In this manner, the heat sink is heated by the temperature-sensitive component during operation, and diffuses such heat into the surrounding atmosphere to manage the temperature of the temperature-sensitive component. However, as discussed above, the amount of thermal load applied to the cooling system is in some cases greater than only the heat generated directly by the temperature-sensitive component. For instance, heat from various other components of an electronic device (e.g., processors, memory chips, power supplies) may diffuse through the device via conduction, convection, and/or radiation, increasing the temperature of the temperature-sensitive component, and thereby increasing the thermal load applied to the cooling system.

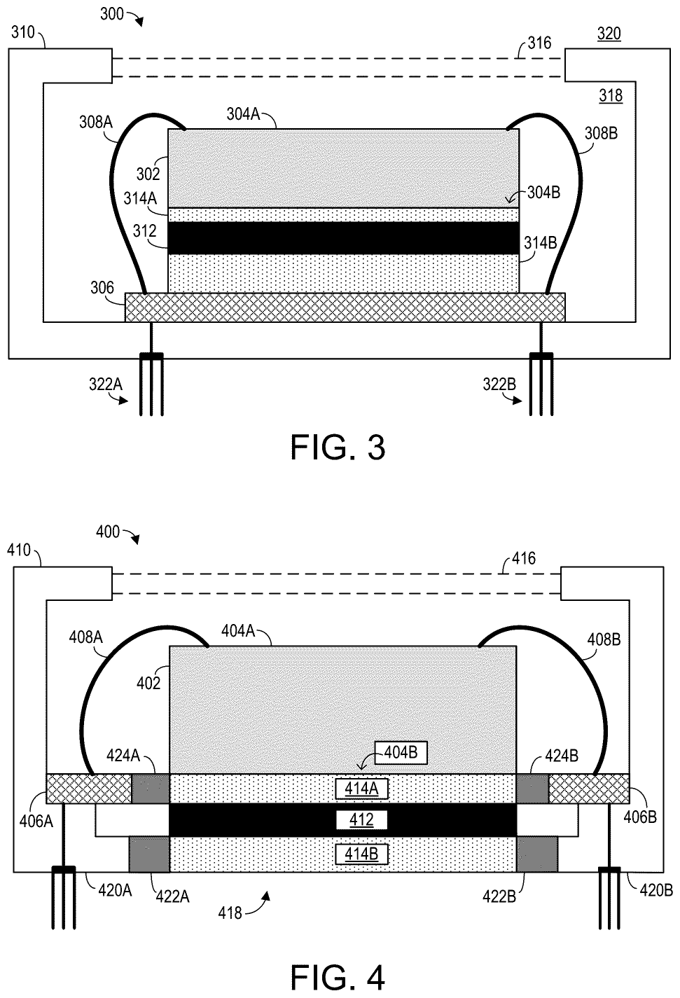

As such, FIG. 2, along with FIGS. 3-7, schematically depict different example arrangements that may beneficially improve the thermal isolation of a temperature-sensitive hardware component from sources of heat in an electronic device. It will be understood that FIGS. 2-7 are non-limiting examples, highly simplified, schematic in nature, and not necessarily drawn to scale. FIGS. 2-7 may include any suitable number of additional or alternative components not specifically described herein.

FIG. 2 schematically shows a sectional view of portions of an example hardware component package 200. As discussed above, a hardware component package includes various structures used to encapsulate a temperature-sensitive hardware component, and provide the temperature-sensitive component with mechanical support, electrical connections, and/or environmental protection to facilitate its functionality within an electronic device. In FIG. 2, the hardware component package includes temperature-sensitive hardware component 202, which may, as one example, take the form of an image sensor. More particularly, in some examples, the temperature-sensitive hardware component is a complementary metal-oxide-semiconductor (CMOS) image sensor or a charge-coupled device (CCD) image sensor. In any case, temperature-sensitive hardware component 202 includes a first surface 204A (e.g., an “upper surface” in the view of FIG. 2) and a second surface 204B (e.g., a “lower surface” in the view of FIG. 2) opposite from the first surface.

The hardware component package additionally includes a substrate 206 coupled with temperature-sensitive hardware component 202 via a wire bond 208 connected to first surface 204A of temperature-sensitive hardware component 202. In some examples, the substrate takes the form of a PCB, and includes electrical traces that facilitate connections between the temperature-sensitive component and other circuitry of the electronic device. In general, however, the substrate includes any suitable material having one or more traces or electrical contacts that are connected to the temperature-sensitive hardware component via one or more wire bonds. Thus, for instance, the substrate may include various material layers, such as fiberglass, suitable metals (e.g., copper, aluminum, iron), resin, and/or other suitable materials. In some examples, the substrate serves as a physical base for the hardware component package.

Although only one is shown in FIG. 2, it will be understood that the substrate and temperature-sensitive component may be connected via any suitable number of wire bonds. For instance, in some examples, two or more wire bonds may be used. A wire bond generally takes the form of any suitable wire that electrically connects a temperature-sensitive component and a substrate in a hardware component package. In some cases, the thermal isolation of the temperature-sensitive component can be influenced by the dimensions and/or material composition of the wire bonds. For instance, in some examples, use of relatively longer and/or thinner wire bonds may reduce heat propagation from the substrate and/or package enclosure to the temperature-sensitive component. Additionally, or alternatively, a wire bond may be formed from a material having a relatively lower thermal conductivity. For instance, in some examples, the material used to form a wire bond may include aluminum or stainless steel. This may result in less heat propagation to the temperature-sensitive component, as compared to wire bonds formed from other metals, such as copper or gold.

Furthermore, it will be understood that a wire bond may be used to connect a temperature-sensitive component and substrate without directly contacting both the temperature-sensitive component and substrate. For instance, in FIG. 2, the wire bond 208 is connected to a trace 209 in a package enclosure 210 of the hardware component package, and the trace serves to couple the wire bond with the substrate by propagating electricity between the wire bond and substrate.

The package enclosure is used to enclose and protect other components of the hardware component package. The package disclosure is described as being coupled with the second surface of the temperature-sensitive hardware component. However, this does not require direct contact between the package enclosure and the temperature-sensitive hardware component. Rather, the package enclosure generally serves as a supporting base for the temperature-sensitive hardware component, even in cases where one or more other components are disposed between the package enclosure and the temperature-sensitive hardware component. For instance, as will be described in more detail below, hardware component package 200 includes a thermoelectric cooler (TEC) 212 disposed between the second surface 204B of temperature-sensitive hardware component 202 and the package enclosure 210.

The package enclosure is constructed from any suitable materials. As one non-limiting example, the package enclosure is at least partially formed from ceramic. In some examples, the package enclosure includes multiple different pieces or structures that are attached together. For instance, as will be described below with respect to FIGS. 4-6, the package enclosure in some cases includes multiple different portions that are separated by a thermal isolation layer to reduce heat propagation between the different portions of the package enclosure.

In FIG. 2, hardware component package 200 additionally includes a TEC 212 disposed between the second surface 204B of the temperature-sensitive hardware component 202 and the package enclosure. In this manner, at least some heat generated by the temperature-sensitive hardware component is dissipated to the package enclosure via the TEC. A TEC, also known as a Peltier device, transfers heat from one side of the device to the other with the help of an electric current. In some examples, a TEC is constructed from a plurality of semiconductor pellets (e.g., Peltier elements) sandwiched between ceramic plates. When an electric current is passed through the Peltier elements, heat is absorbed at one junction and released at another junction. In this manner, the side of the TEC that absorbs heat becomes cold, and the opposite side, where heat is released, becomes hot. As such, the cold side may be attached to the temperature-sensitive hardware component, while the hot side may be attached to a suitable component for dissipating heat from the temperature-sensitive component (e.g., the package enclosure).

Turning now to FIG. 3, another schematic sectional view is provided of an example hardware component package 300. Similar to package 200, package 300 includes a temperature-sensitive hardware component 302, having a first surface 304A and a second surface 304B. The temperature-sensitive hardware component is connected to a substrate 306 via wire bonds 308A and 308B. Each of these elements are enclosed by a package enclosure 310. A TEC 312 is disposed between the second surface 304B of the temperature-sensitive hardware component 302, and the package enclosure 310.

In this example, the hardware component package additionally includes heat spreaders 314A and 314B between the temperature-sensitive hardware component and the package enclosure. Any suitable material may be used as a heat spreader depending on the implementation, in order to balance various factors such as weight, cost, and thermal conductivity. As non-limiting examples, heat spreaders may be formed partially or entirely from copper, aluminum, graphite, silver, etc. Using a heat spreader can mitigate uneven heat generation from the temperature-sensitive hardware component (and/or from other heat sources), and/or mitigate uneven cooling (e.g., from an undersized TEC).

In some examples, the package enclosure further comprises a transparent glass cover facing the first surface of the temperature-sensitive hardware component. This is the case in FIG. 3, where hardware component package 300 includes a transparent glass cover 316. For instance, when the temperature-sensitive hardware component is implemented as an image sensor, use of a glass cover may permit light to enter the image sensor package and strike the upper surface of the image sensor. It will be understood that any suitable type of glass may be used, which may have any suitable degree of transparency to visible and/or other wavelengths of light, depending on the implementation.

In some examples, the package enclosure is an airtight package enclosure that separates a package atmosphere from an external atmosphere. This is the case in FIG. 3, where the hardware component package is airtight, and thus has an internal package atmosphere 318 that is separate from external atmosphere 320. In some examples, the package atmosphere has a package gas composition with a lower thermal conductivity than a gas composition of the external atmosphere—e.g., the hardware component package may be filled with a gas that has a lower thermal conductivity than normal earth atmospheric air. As non-limiting examples, the hardware component package atmosphere may include nitrogen, argon, krypton, xenon, and/or other suitable gases. Alternatively, in some examples, the hardware component package may be vacuum-packed—e.g., substantially all air is removed from the hardware component package before it is sealed. These approaches may beneficially reduce heat diffusion through the hardware component package via conduction and/or convection, improving the thermal isolation of the temperature-sensitive hardware component.

As discussed above, components of the hardware component package are in some examples communicatively coupled with other circuitry of an electronic device. For instance, in this manner, data recorded by an image sensor may be transmitted to a separate logic controller, such as is shown in FIG. 1. To this end, in FIG. 3, the hardware component package includes a communication interface that communicatively couples the substrate 306 with other components of a larger electronic device, such as a logic controller. Specifically, in FIG. 3, the hardware component package includes two such communication interfaces 322A and 322B, which generally take the form of wires or traces that extend from the substrate, and thereby can propagate electrical signals generated by the temperature-sensitive hardware component. It will be understood that a hardware component package may include any suitable number of such communication interfaces, each of which may take any suitable form.

FIG. 4 shows another schematic sectional view of an example hardware component package 400. Similar to packages 200 and 300, package 400 includes a temperature-sensitive hardware component 402, having a first surface 404A and a second surface 404B. The temperature-sensitive hardware component is connected to a substrate 406 via wire bonds 408A and 408B. Each of these elements are enclosed by a package enclosure 410. The hardware component package additionally includes a TEC 412, heat spreaders 414A and 414B, and a glass cover 416.

However, in comparison to package 300, the specific arrangement of the package enclosure and substrate in package 400 is different. As shown, the temperature-sensitive hardware component is coupled with a TEC 412 and heat spreaders 414A and 414B. In this example, substrate 406 wraps around the first heat spreader 414A, and thus is visible in this sectional view as substrate portions 406A and 406B.

Furthermore, in this example, the package enclosure is divided into different portions—e.g., a central portion and a lateral portion. This can in some cases beneficially reduce propagation of heat generated by the temperature-sensitive hardware component from returning to the component via the wire bonds. For instance, in some arrangements, heat originating from the temperature-sensitive hardware component may be propagated to the package enclosure—e.g., via cooling by the TEC, as discussed above. From there, in some scenarios, heat can be conducted through the package enclosure to the wire bonds, which then conduct the heat back to the temperature-sensitive hardware component. This is not ideal and can increase the thermal load on the cooling system.

As such, in the example of FIG. 4, package enclosure 410 includes a central portion 418 that contacts the TEC 412. In this example, the central portion of the package enclosure takes the form of the second heat spreader 414B, although this is non-limiting-rather, in some cases, the central portion of the package enclosure may be implemented as a separate component (e.g., a separate piece of ceramic) that is attached to the heat spreader, or other suitable component. The package enclosure additionally includes a lateral portion 420A, which is formed from a separate piece of material from the central portion. Another lateral portion 420B is shown on the other side of the central portion. However, it will be understood that in some cases, the lateral portions 420A and 420B are formed from the same continuous piece of material, and only appear to be separate in the sectional view of FIG. 4.

The lateral portions of the package enclosure are thermally coupled with the wire bonds 408A and 408B connected to the temperature-sensitive hardware component. “Thermally coupled,” as used herein, means that the temperature of the wire bonds influences the temperature of the lateral portions of the package enclosure, and vice versa. The central portion 418 and the lateral portions 420A and 420B are separated by thermal isolation layers 422A and 422B at the interfaces between the central and lateral portions. This may function to reduce propagation of heat from the central portion (e.g., originating from the temperature-sensitive hardware component) to the lateral portion, and therefore reduce propagation of heat back to the temperature-sensitive hardware component via the wire bonds. As such, in some examples, the thermal isolation layers 422A and 422B include a material having a lower thermal conductivity than the central portion and the lateral portion of the package enclosure. As one non-limiting example, the thermal isolation layers may include epoxy, although any suitable thermally insulating material may be used.

Furthermore, in the example of FIG. 4, thermal isolation layers 424A and 424B are included between the first heat spreader 414A and the substrate portions 406A and 406B. This may serve to reduce propagation of heat from the lateral portion of the package enclosure to the temperature-sensitive hardware component through the thermal isolation layers 424A and 424B. Similar to thermal isolation layers 422A and 422B, layers 424A and 424B may include any suitable thermally insulating materials, such as epoxy as one non-limiting example.

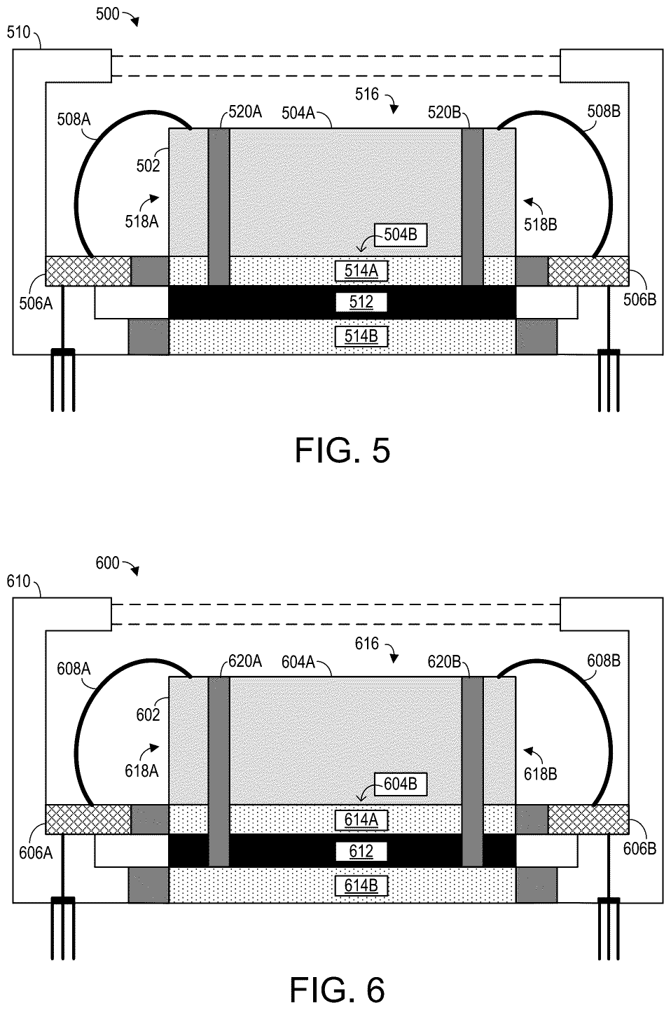

FIG. 5 shows another schematic sectional view of an example hardware component package 500. Similar to package 400, hardware component package 500 includes a temperature-sensitive hardware component 502, having a first surface 504A and a second surface 504B. The temperature-sensitive hardware component is connected to a substrate 506 via wire bonds 508A and 508B. Each of these elements are enclosed by a package enclosure 510. The hardware component package additionally includes a TEC 512 and heat spreaders 514A and 514B.

In this example, the temperature-sensitive hardware component takes the form of an image sensor. The image sensor includes a photodiode portion 516, which includes a plurality of photosensitive elements that exhibit changes in electrical conditions when exposed to light. Additionally, the image sensor includes an edge portion 518A. Wire bond 508A is attached to edge portion 518A of the image sensor. A second edge portion 518B is shown on the other side of the photodiode portion, and attached to the second wire bond 508B. However, it will be understood that the two edge portions may in some cases be formed from a single continuous piece of material (e.g., defining a ring around the photodiode portion), and only appear to be separate in the sectional view of FIG. 5.

In this example, the image sensor includes a thermal isolation trench 520A between edge portion 518A and photodiode portion 516. This serves to reduce heat transfer from the edge portion to the photodiode portion. As discussed above, in some examples, heat originating from the temperature-sensitive hardware component, and/or other components of the electrical device, may be propagated to the temperature-sensitive hardware component via the wire bonds. Furthermore, in some examples, the photodiode portion of the image sensor exhibits performance degradation as its temperature increases. As such, use of a thermal isolation trench such as is shown in FIG. 5 can reduce the amount of heat that is propagated to the photodiode portion from the edge portion.

FIG. 5 additionally shows a second thermal isolation trench 520B separating photodiode portion 516 from edge portion 518B. However, as discussed above, the two edge portions 518A and 518B may in some cases be formed from the same continuous piece of material. Thus, the thermal isolation trenches 520A and 520B may be a single continuous trench—e.g., forming a ring around the photodiode portion of the image sensor.

The thermal isolation trench may include any suitable material having lower thermal conductivity than the base material of the image sensor. In some examples, the thermal isolation trench is empty—e.g., only filled by any gases in the package atmosphere of the hardware component package. In other examples, suitable thermally isolating materials may be included in the thermal isolation trench to reduce heat propagation from the edge portion to the photodiode portion. As one non-limiting example, portions of the thermal isolation trench that extend through an image sensor die may include silicon oxide.

The thermal isolation trench may have any suitable depth. In the example of FIG. 5, the thermal isolation trench extends through the image sensor and into the first heat spreader 514A. However, this is non-limiting. For instance, in some examples, the thermal isolation trench may have a shorter depth—e.g., not extending all the way through the image sensor.

Alternatively, in some examples, the thermal isolation trench may have a greater depth than is shown in FIG. 5. For example, FIG. 6 shows another schematic sectional view of an example hardware component package 600. Similar to package 500, hardware component package 600 includes a temperature-sensitive hardware component 602, having a first surface 604A and a second surface 604B. The temperature-sensitive hardware component is connected to a substrate 606 via wire bonds 608A and 608B. Each of these elements are enclosed by a package enclosure 610. The hardware component package additionally includes a TEC 612 and heat spreaders 614A and 614B.

Similar to hardware component package 500, the temperature-sensitive component 602 takes the form of an image sensor having a photodiode portion 616 and an edge portion 618A/B, which are separated by a thermal isolation trench 620A/B. In this example, the thermal isolation trench has a greater depth than is shown in FIG. 5. Specifically, in this example, the thermal isolation trench extends into the TEC. This can further reduce heat propagation from the edge portion of the image sensor to the photodiode portion. In some examples, operation of the TEC may be controlled to provide differential cooling to the photodiode portion and the edge portion of the image sensor—e.g., relatively more power may be used at the TEC to cool the photodiode portion, where such cooling will have a greater effect on image sensor performance, as compared to cooling the edge portion. As non-limiting examples, portions of a thermal isolation trench that extend into a TEC may be empty, or filled with epoxy, to reduce heat propagation.

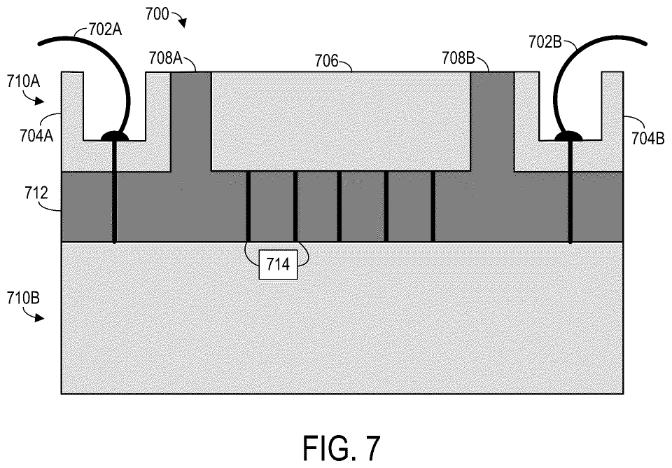

FIG. 7 shows a schematic sectional view of an example image sensor 700, which may be included in a hardware component package as described above. As shown, the image sensor is connected to wire bonds 702A and 702B, which may electrically connect the image sensor to a substrate as described above. Furthermore, as described above, the image sensor includes an edge portion 704A/B and a photodiode portion 706, separated by thermal isolation trench 708A/B. In this example, the image sensor includes a first layer 710A and a second layer 710B. The edge portion and photodiode portion are integrated into the first layer. The first layer and the second layer are separated by a sensor thermal isolation layer 712, and the thermal isolation trench 708A/B extends into the sensor thermal isolation layer. Similar to the thermal isolation trench, the sensor thermal isolation layer may include any suitable thermally-isolating materials having a lower thermal conductivity than the base material of the image sensor.

This arrangement may serve to improve the thermal isolation between the first layer and the second layer of the image sensor. For instance, as discussed above, the photodiode portion may exhibit degraded performance as its temperature increases. Furthermore, some amount of heat may be generated in the second layer of the image sensor during operation—e.g., caused by data readout and/or other suitable operations. As such, use of the sensor thermal isolation layer can reduce propagation of heat from the second layer back to the photodiode portion.

The first layer and the second layer of the image sensor are electrically coupled via one or more conductive wires extending between the first layer and the second layer, through the sensor thermal isolation layer. In the example of FIG. 7, the image sensor includes a plurality of conductive wires 714. It will be understood that any suitable arrangement and distribution of such wires may be used, and each wire may be formed from any suitable material, depending on the implementation. In this manner, power and/or data may be propagated between the first and second layers by way of the conductive wires.

This disclosure is presented by way of example and with reference to the associated drawing figures. Components, process steps, and other elements that may be substantially the same in one or more of the figures are identified coordinately and are described with minimal repetition. It will be noted, however, that elements identified coordinately may also differ to some degree. It will be further noted that some figures may be schematic and not drawn to scale. The various drawing scales, aspect ratios, and numbers of components shown in the figures may be purposely distorted to make certain features or relationships easier to see.

In an example, a hardware component package comprises: a temperature-sensitive hardware component having a first surface and a second surface opposite from the first surface; a substrate coupled with the temperature-sensitive hardware component via a wire bond connected to the first surface of the temperature-sensitive hardware component; a package enclosure coupled with the second surface of the temperature-sensitive hardware component, the package enclosure including a central portion and a lateral portion that is thermally coupled with the wire bond, the central portion and the lateral portion formed from separate pieces of material and separated by a thermal isolation layer at an interface between the central portion and the lateral portion; and a thermoelectric cooler (TEC) disposed between the second surface of the temperature-sensitive hardware component and the package enclosure, the TEC contacting the central portion of the package enclosure, such that at least some heat generated by the temperature-sensitive hardware component is dissipated to the package enclosure via the TEC. In this example or any other example, the thermal isolation layer includes a material having a lower thermal conductivity than the central portion and the lateral portion of the package enclosure. In this example or any other example, the package enclosure is an airtight package enclosure that separates a package atmosphere from an external atmosphere. In this example or any other example, the package atmosphere includes a package gas composition having a lower thermal conductivity than an external atmospheric gas composition of the external atmosphere. In this example or any other example, the airtight package enclosure is vacuum-packed. In this example or any other example, the temperature-sensitive hardware component is an image sensor, wherein the image sensor includes a photodiode portion and an edge portion, and wherein the wire bond is connected to the edge portion of the image sensor. In this example or any other example, the image sensor includes a thermal isolation trench between the edge portion and the photodiode portion to reduce heat transfer from the edge portion to the photodiode portion. In this example or any other example, the image sensor includes a first layer separated from a second layer by a sensor thermal isolation layer, and wherein the thermal isolation trench between the edge portion and the photodiode portion extends into the sensor thermal isolation layer. In this example or any other example, the first layer of the image sensor is electrically coupled with the second layer via one or more conductive wires extending between the first layer and the second layer, through the sensor thermal isolation layer. In this example or any other example, the thermal isolation trench extends into the TEC. In this example or any other example, the package enclosure is at least partially formed from ceramic. In this example or any other example, the package enclosure further comprises a transparent glass cover facing the first surface of the temperature-sensitive hardware component. In this example or any other example, the wire bond comprises a material selected from a group including aluminum and stainless steel. In this example or any other example, the temperature-sensitive hardware component is a complementary metal-oxide-semiconductor (CMOS) image sensor or a charge-coupled device (CCD) image sensor.

In an example, an image sensor package comprises: an image sensor having a first surface and a second surface opposite from the first surface, the image sensor including a photodiode portion and an edge portion, and the image sensor including a thermal isolation trench between the edge portion and the photodiode portion to reduce heat transfer from the edge portion to the photodiode portion; a substrate coupled with the image sensor via a wire bond connected to the edge portion of the image sensor; a package enclosure coupled with the second surface of the image sensor; and a thermoelectric cooler (TEC) disposed between the second surface of the image sensor and the package enclosure, such that at least some heat generated by the image sensor is dissipated to the package enclosure via the TEC. In this example or any other example, the package enclosure includes a central portion that contacts the TEC, a lateral portion that is thermally coupled with the wire bond connected to the edge portion of the image sensor, and a thermal isolation layer at an interface between the central portion and the lateral portion, the thermal isolation layer having a lower thermal conductivity than the central portion and the lateral portion of the package enclosure. In this example or any other example, the package enclosure is an airtight package enclosure that separates a package atmosphere from an external atmosphere. In this example or any other example, the thermal isolation trench extends into the TEC. In this example or any other example, the image sensor includes a first layer separated from a second layer by a sensor thermal isolation layer, and wherein the thermal isolation trench between the edge portion and the photodiode portion extends into the sensor thermal isolation layer.

In an example, an electronic device comprises: a logic controller; and a hardware component package communicatively coupled with the logic controller, the hardware component package comprising: a temperature-sensitive hardware component having a first surface and a second surface opposite from the first surface; a substrate coupled with the temperature-sensitive hardware component via a wire bond connected to the first surface of the temperature-sensitive hardware component; a package enclosure coupled with the second surface of the temperature-sensitive hardware component, the package enclosure including a central portion and a lateral portion that is thermally coupled with the wire bond, the central portion and the lateral portion formed from separate pieces of material and separated by a thermal isolation layer at an interface between the central portion and the lateral portion; a thermoelectric cooler (TEC) disposed between the second surface of the temperature-sensitive hardware component and the package enclosure, the TEC contacting the central portion of the package enclosure, such that at least some heat generated by the temperature-sensitive hardware component is dissipated to the package enclosure via the TEC; and a communication interface communicatively coupling the substrate with the logic controller.

It will be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated and/or described may be performed in the sequence illustrated and/or described, in other sequences, in parallel, or omitted. Likewise, the order of the above-described processes may be changed.

The subject matter of the present disclosure includes all novel and non-obvious combinations and sub-combinations of the various processes, systems and configurations, and other features, functions, acts, and/or properties disclosed herein, as well as any and all equivalents thereof.

1. A hardware component package, comprising:
a temperature-sensitive hardware component having a first surface and a second surface opposite from the first surface;
a substrate coupled with the temperature-sensitive hardware component via a wire bond connected to the first surface of the temperature-sensitive hardware component;
a package enclosure coupled with the second surface of the temperature-sensitive hardware component, the package enclosure including a central portion and a lateral portion that is thermally coupled with the wire bond, the central portion and the lateral portion formed from separate pieces of material and separated by a thermal isolation layer at an interface between the central portion and the lateral portion; and
a thermoelectric cooler (TEC) disposed between the second surface of the temperature-sensitive hardware component and the package enclosure, the TEC contacting the central portion of the package enclosure, such that at least some heat generated by the temperature-sensitive hardware component is dissipated to the package enclosure via the TEC.

2. The hardware component package of claim 1, wherein the thermal isolation layer includes a material having a lower thermal conductivity than the central portion and the lateral portion of the package enclosure.

3. The hardware component package of claim 1, wherein the package enclosure is an airtight package enclosure that separates a package atmosphere from an external atmosphere.

4. The hardware component package of claim 3, wherein the package atmosphere includes a package gas composition having a lower thermal conductivity than an external atmospheric gas composition of the external atmosphere.

5. The hardware component package of claim 3, wherein the airtight package enclosure is vacuum-packed.

6. The hardware component package of claim 1, wherein the temperature-sensitive hardware component is an image sensor, wherein the image sensor includes a photodiode portion and an edge portion, and wherein the wire bond is connected to the edge portion of the image sensor.

7. The hardware component package of claim 6, wherein the image sensor includes a thermal isolation trench between the edge portion and the photodiode portion to reduce heat transfer from the edge portion to the photodiode portion.

8. The hardware component package of claim 7, wherein the image sensor includes a first layer separated from a second layer by a sensor thermal isolation layer, and wherein the thermal isolation trench between the edge portion and the photodiode portion extends into the sensor thermal isolation layer.

9. The hardware component package of claim 8, wherein the first layer of the image sensor is electrically coupled with the second layer via one or more conductive wires extending between the first layer and the second layer, through the sensor thermal isolation layer.

10. The hardware component package of claim 7, wherein the thermal isolation trench extends into the TEC.

11. The hardware component package of claim 1, wherein the package enclosure is at least partially formed from ceramic.

12. The hardware component package of claim 11, wherein the package enclosure further comprises a transparent glass cover facing the first surface of the temperature-sensitive hardware component.

13. The hardware component package of claim 1, wherein the wire bond comprises a material selected from a group including aluminum and stainless steel.

14. The hardware component package of claim 1, wherein the temperature-sensitive hardware component is a complementary metal-oxide-semiconductor (CMOS) image sensor or a charge-coupled device (CCD) image sensor.

15. An image sensor package, comprising:
an image sensor having a first surface and a second surface opposite from the first surface, the image sensor including a photodiode portion and an edge portion, and the image sensor including a thermal isolation trench between the edge portion and the photodiode portion to reduce heat transfer from the edge portion to the photodiode portion;
a substrate coupled with the image sensor via a wire bond connected to the edge portion of the image sensor;
a package enclosure coupled with the second surface of the image sensor; and
a thermoelectric cooler (TEC) disposed between the second surface of the image sensor and the package enclosure, such that at least some heat generated by the image sensor is dissipated to the package enclosure via the TEC.

16. The image sensor package of claim 15, wherein the package enclosure includes a central portion that contacts the TEC, a lateral portion that is thermally coupled with the wire bond connected to the edge portion of the image sensor, and a thermal isolation layer at an interface between the central portion and the lateral portion, the thermal isolation layer having a lower thermal conductivity than the central portion and the lateral portion of the package enclosure.

17. The image sensor package of claim 15, wherein the package enclosure is an airtight package enclosure that separates a package atmosphere from an external atmosphere.

18. The image sensor package of claim 15, wherein the thermal isolation trench extends into the TEC.

19. The image sensor package of claim 15, wherein the image sensor includes a first layer separated from a second layer by a sensor thermal isolation layer, and wherein the thermal isolation trench between the edge portion and the photodiode portion extends into the sensor thermal isolation layer.

20. An electronic device, comprising:
a logic controller; and
a hardware component package communicatively coupled with the logic controller, the hardware component package comprising:
a temperature-sensitive hardware component having a first surface and a second surface opposite from the first surface;
a substrate coupled with the temperature-sensitive hardware component via a wire bond connected to the first surface of the temperature-sensitive hardware component;
a package enclosure coupled with the second surface of the temperature-sensitive hardware component, the package enclosure including a central portion and a lateral portion that is thermally coupled with the wire bond, the central portion and the lateral portion formed from separate pieces of material and separated by a thermal isolation layer at an interface between the central portion and the lateral portion;
a thermoelectric cooler (TEC) disposed between the second surface of the temperature-sensitive hardware component and the package enclosure, the TEC contacting the central portion of the package enclosure, such that at least some heat generated by the temperature-sensitive hardware component is dissipated to the package enclosure via the TEC; and
a communication interface communicatively coupling the substrate with the logic controller.
